(19) United States
(12) Patent Application Publication
(10) Pub. No.: US 2017/0236573 A1
(43) Pub. Date: Aug. 17, 2017

(54) SEMICONDUCTOR DEVICE INCLUDING SENSE AMPLIFIER HAVING POWER DOWN

(71) Applicant: SK hynix Inc., Gyeonggi-do (KR)

(72) Inventor: Sung-Ho KIM, Gyeonggi-do (KR)

(21) Appl. No.: 15/186,181

(22) Filed: Jun. 17, 2016

(30) Foreign Application Priority Data
Feb. 16, 2016 (KR) 10-2016-0017716

(51) Int. Cl. G11C 11/4094; G11C 11/4096; G11C 11/4091

(52) U.S. Cl. CPC G11C 11/4094; G11C 11/4091; G11C 11/4096

(57) ABSTRACT

This technology relates to a semiconductor device. The semiconductor device may include a sense amplification unit suitable for sensing and amplifying data loaded onto a data line pair, and a voltage supply unit suitable for supplying a pull-down power line with a first voltage in response to a pull-down driving signal in an active mode, and for supplying the pull-down power line with a second voltage having a higher voltage level than the first voltage in response to the pull-down driving signal during an initial period of the active mode.

### CROSS-REFERENCE TO RELATED APPLICATION(S)

The present application claims priority under 35 U.S.C. §119(a) to Korean Patent Application No. 10-2016-0017716, filed on Feb. 16, 2016, which is incorporated herein by reference in its entirety.

### BACKGROUND

1. Field

Exemplary embodiments of the present invention relate to a semiconductor design technology and, more particularly, to a semiconductor memory device including a sense amplification unit.

2. Description of the Related Art

A Dynamic random access memory (DRAM) is an example of a volatile semiconductor memory device. A memory cell of a DRAM includes a cell transistor and a cell capacitor. The cell transistor functions to select the cell capacitor, and the cell capacitor stores charges corresponding to data.

A memory cell needs to copy and re-store corresponding data periodically because charges are introduced into or drained from the cell capacitor of the memory cell due to a leakage component. Such an operation is typically performed periodically for retaining the data stored in a DRAM and is known as a refresh operation. In a refresh operation, an active mode and a precharge mode are repeatedly performed at a specific cycle. In the active mode, a memory cell is selected. When a bit line sense amplification unit is activated, it senses data transferred by the selected memory cell, amplifies the sensed data, and transfers the amplified data to the memory cell again. In the precharge mode, the memory cell is not selected. When the bit line sense amplification unit is deactivated, the unselected memory cell retains stored data.

If the leakage component is increased the data retention time of the memory cell which is the time the memory cell can retain reliably the data stored in the cell capacitor after a precharge operation is reduced. Accordingly, there is a need for a technology for improving such a problem.

### SUMMARY

Various embodiments are directed to a semiconductor device having a reduced off current.

In an embodiment, a semiconductor device may include a sense amplification unit suitable for sensing and amplifying data loaded onto a data line pair; and a voltage supply unit suitable for supplying a pull-down power line with a first voltage in response to a pull-down driving signal in an active mode, and for supplying the pull-down power line with a second voltage having a higher voltage level than the first voltage in response to the pull-down driving signal during an initial period of the active mode.

The voltage supply unit may include a first pull-down driving unit suitable for supplying the pull-down power line with the first voltage in response to the pull-down driving signal in the active mode; and a second pull-down driving unit suitable for supplying the pull-down power line with the second voltage in response to the pull-down driving signal during the initial period of the active mode.

The semiconductor device may further include a pull-down control unit suitable for controlling whether or not to enable the pull-down driving signal during the initial period of the active mode.

The pull-down control unit may perform control so that the pull-down driving signal is disabled during a power-down mode period of the active mode.

The pull-down control unit may perform control so that the pull-down driving signal is disabled during a continuous write operation period of the active mode.

The semiconductor device may further include a pull-up driving unit suitable for supplying a pull-up power line with a third voltage having a higher voltage level than the second voltage as a pull-up driving voltage in response to a pull-up driving signal in the active mode.

The first voltage may include an externally supplied ground voltage, the third voltage includes a core voltage generated by lowering an externally supplied power supply voltage, and the second voltage includes a bit line precharge voltage corresponding to half of the core voltage.

The semiconductor device may further include a first precharge unit suitable for precharging the data line pair to the precharge voltage in a precharge mode after the active mode; and a second precharge unit suitable for precharging the pull-up power line and the pull-down power line to the precharge voltage in the precharge mode.

In an embodiment, a semiconductor device may include a bit line pair including a main bit line and a sub-bit line; a memory cell coupled to any one of the main bit line and the sub-bit line; a sense amplification unit suitable for sensing and amplifying data loaded onto the bit line pair; a pull-up driving unit suitable for supplying a pull-up power line with a first voltage in response to a pull-up driving signal in an active mode; and a pull-down driving unit suitable for supplying a pull-down power line with a second voltage having a lower voltage level than the first voltage in response to a pull-down driving signal in the active mode, wherein the pull-down driving unit supplies the pull-down power line with a third voltage having a lower voltage level than the first voltage and having a higher voltage level than the second voltage in response to the pull-down driving signal during an initial period of the active mode.

The pull-down driving unit may include a first pull-down driving unit suitable for supplying the pull-down power line with the second voltage in response to the pull-down driving signal in the active mode; and a second pull-down driving unit suitable for supplying the pull-down power line with the third voltage in response to the pull-down driving signal during the initial period of the active mode.

The semiconductor device may further include a pull-down control unit suitable for controlling whether or not to enable the pull-down driving signal during the initial period of the active mode.

The pull-down control unit may perform control so that the pull-down driving signal is disabled during a power-down mode period of the active mode.

The pull-down control unit may perform control so that the pull-down driving signal is disabled during a continuous write operation period of the active mode.

The first voltage may include a core voltage generated by lowering an external power supply voltage, the second voltage may include an externally supplied ground voltage, and the third voltage may include a bit line precharge voltage corresponding to half of the core voltage.

The semiconductor device may further include a first precharge unit suitable for precharging the data line pair to the precharge voltage in a precharge mode after the active mode; and a second precharge unit suitable for precharging the pull-up power line and the pull-down power line to the precharge voltage in the precharge mode.

### BRIEF DESCRIPTION OF THE DRAWINGS

FIG. 1 is a circuit diagram of a semiconductor device, according to an embodiment of the present invention.

FIG. 2 is a timing diagram illustrating an operation of the semiconductor device shown in FIG. 1, according to an embodiment of the invention.

FIG. 3 is a circuit diagram of a pull-down control unit shown in FIG. 1, according to an embodiment of the invention.

### DETAILED DESCRIPTION

Various embodiments will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the present invention to those skilled in the art. Throughout the disclosure, like reference numerals refer to like parts throughout the various figures and embodiments of the present invention.

It will be understood that, although the terms “first”, “second”, “third”, and so on may be used herein to describe various elements, these elements are not limited by these terms. These terms are used to distinguish one element from another element. Thus, a first element described below could also be termed as a second or third element without departing from the spirit and scope of the present invention.

The drawings are not necessarily to scale and, in some instances, proportions may have been exaggerated in order to clearly illustrate features of the embodiments.

It will be further understood that when an element is referred to as being “connected to”, or “coupled to” another element, it may be directly on, connected to, or coupled to the other element, or one or more intervening elements may be present. In addition, it will also be understood that when an element is referred to as being “between” two elements, it may be the only element between the two elements, or one or more intervening elements may also be present.

The terminology used herein is for the purpose of describing particular embodiments only and is not intended to be limiting of the present invention. As used herein, singular forms are intended to include the plural forms as well, unless the context clearly indicates otherwise. It will be further understood that the terms “comprises”, “comprising”, “includes”, and “Including” when used in this specification, specify the presence of the stated elements and do not preclude the presence or addition of one or more other elements. As used herein, the term “and/or” includes any and all combinations of one or more of the associated listed items.

Unless otherwise defined, all terms including technical and scientific terms used herein have the same meaning as commonly understood by one of ordinary skill in the art to which the present invention belongs. It will be further understood that terms, such as those defined in commonly used dictionaries, should be interpreted as having a meaning that is consistent with their meaning in the context of the specification and relevant art and will not be interpreted in an idealized or overly formal sense unless expressly so defined herein.

In the following description, numerous specific details are set forth in order to provide a thorough understanding of the present invention. The present invention may be practiced without some or all of these specific details. In other instances, well-known process structures and/or processes have not been described in detail in order not to unnecessarily obscure the present invention.

It is also noted, that in some instances, as would be apparent to those skilled in the relevant art, a feature or element described in connection with one embodiment may be used singly or in combination with other features or elements of another embodiment, unless otherwise specifically indicated.

Hereinafter, the various embodiments of the present invention will be described in detail with reference to the attached drawings.

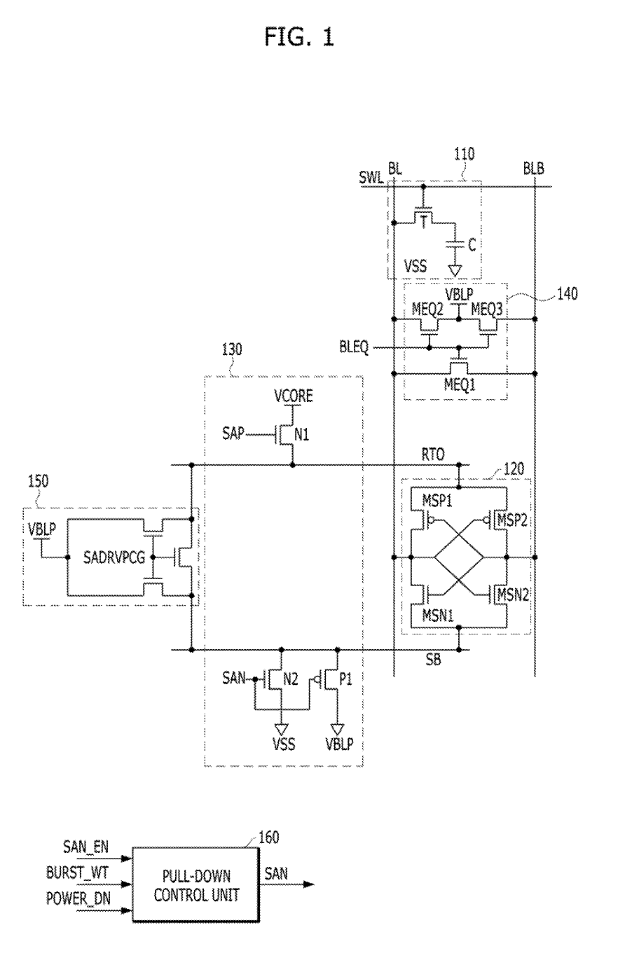

Referring now to FIG. 1, a semiconductor device is provided, according to an embodiment of the present invention.

According to the embodiment of FIG. 1, the semiconductor device may include a bit line pair including a main bit line BL and a sub-bit line BLB, a memory cell 110, a sense amplification unit 120, a voltage supply unit 130, a first precharge unit 140, a second precharge unit 150, and a pull-down control unit 160.

The memory cell 110 may be coupled to any one of the main bit line BL and the sub-bit line BLB. In the illustrated embodiment of FIG. 1, the memory cell is coupled to the main bit line. The memory cell 110 may include a cell capacitor C configured to store data and a cell transistor T configured to control charge sharing between any one of the main bit line BL and the sub-bit line BLB and the cell capacitor C. For example, the cell capacitor C may include a capacitor coupled between a ground voltage (VSS) stage and a capacitor storage node. The cell transistor T may include an NMOS transistor having a gate coupled to a word line WL and a source and drain coupled between the capacitor storage node and the main bit line BL.

The sense amplification unit 120 is a bit line sense amplifier (BLSA). The sense amplification unit 120 senses data loaded onto the bit line pair BL and BLB and amplifies the sensed data to a driving voltage supplied through a pull-up power line RTO and a pull-down power line SB. For example, the sense amplification unit 120 may include a cross-couple latch amplifier including PMOS transistors transistors MSP1 and MSP2 and NMOS transistors MSN1 and MSN2.

The voltage supply unit 130 may include a pull-up driving unit including an NMOS transistor N1 and a pull-down driving unit including an NMOS transistor N2 and a PMOS transistor P1. The pull-up driving unit N1 may drive the pull-up power line RTO to a core voltage VCORE during an active period in response to a pull-up driving signal SAP. The NMOS transistor N1 has a gate to which the pull-up driving signal SAP is inputted and a source and drain coupled between a core voltage (VCORE) stage and the pull-up power line RTO.

The NMOS transistor N2 of the pull-down driving unit may drive the pull-down power line SB to the ground voltage VSS during an active period in response to a pull-down driving signal SAN. The PMOS transistor P1 is configured to drive the pull-down power line SB to a bit line precharge voltage VBLP in standby mode of an active period or during a continuous write operation period in response to the pull-down driving signal SAN. The NMOS transistor N2 of the pull-down driving unit has a gate to which the pull-down driving signal SAN is inputted and a source and drain coupled between the ground voltage (VSS) stage and the pull-down power line SB. The PMOS transistor P1 of the pull-down driving unit has a gate to which the pull-down driving signal SAN is inputted and a source and drain coupled between a bit line precharge voltage (VBLP) stage and the pull-down power line SB.

For reference, the core voltage VCORE and the bit line precharge voltage VBLP may be internal voltages internally generated using a power supply voltage VDD that is applied from the outside. For example, the core voltage VCORE may be generated by lowering the power supply voltage VDD, and the bit line precharge voltage VBLP may be generated by lowering the core voltage VCORE (i.e., VBLP=VCORE/2).

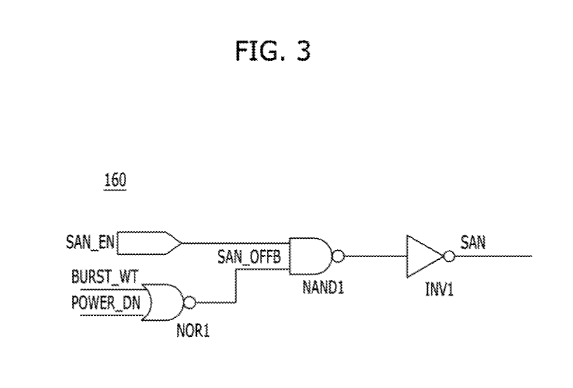

The pull-down control unit 160 controls the enabling of the pull-down driving signal SAN in response to a combination of a burst write signal BURST_WT, a power-down mode signal POWER_DN, and a pull-down control signal SAN_EN. The burst write signal BURST_WT may be enabled when a continuous write operation is performed. The power-down mode signal POWER_DN may be enabled in a standby mode. The pull-down control unit 160 is described in more detail later with reference to FIG. 3.

The first precharge unit 140 includes NMOS transistors MEQ1, MEQ2, and MEQ3 and may precharge the bit line pair BL and BLB to a bit line precharge voltage VBLP during a precharge mode in response to an equalization signal BLEQ applied to the gates of the transistors MEQ1, MEQ2, MEQ3.

The second precharge unit 150 may precharge the pull-up power line RTO and the pull-down power line SB to the bit line precharge voltage VBLP during the precharge mode in response to a precharge signal SADRVPCG.

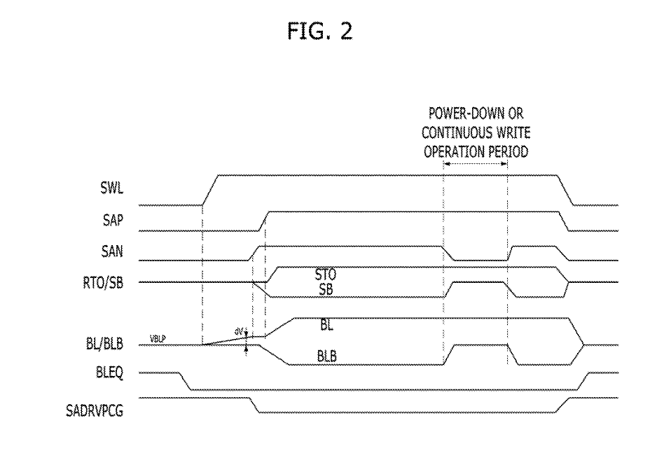

The operation of the semiconductor device configured as described above according to an embodiment of the present invention is described below with reference to FIG. 2.

FIG. 2 is a timing diagram illustrating the operation of the semiconductor device shown in FIG. 1.

According to the embodiment of FIGS. 1 and 2, a sub-word line SWL may be activated to a high logic level in an active mode and may be deactivated to a logic low level in a precharge mode. For example, the sub-word line SWL may be activated in response to an active command (not shown) and may be deactivated in response to a precharge command (not shown).

Furthermore, the pull-up driving signal SAP and the pull-down driving signal SAN may be enabled during the remaining period of active mode after an initial period of the active mode. In this case, the pull-up driving signal SAP and the pull-down driving signal SAN may be generated as a combination of the active command and the precharge command.

When the cell transistor T is turned on in the active mode, charge sharing is performed between the main bit line BL and cell capacitor C of the memory cell 110. If data of a high logic level has been stored in the cell capacitor C, the main bit line BL may rise from the level of the bit line precharge voltage VBLP to a predetermined voltage level. Accordingly, a predetermined voltage difference dV may be generated between the main bit line BL and the sub-bit line BLB.

In this state, in response to the pull-up driving signal SAP, the NMOS transistor N1 is switched on and drives the pull-up power line RTO to the core voltage VCORE during the remaining period of the active mode after an initial period of the active mode. The NMOS transistor N2 is switched on and drives the pull-down power line SB to the ground voltage VSS during the remaining period of the active mode in response to the pull-down driving signal SAN. Accordingly, the sense amplification unit 120 amplifies a voltage level of the main bit line BL to the core voltage VCORE during the remaining period of the active mode after an initial period of the active mode and amplifies a voltage level of the sub-bit line BLB to the ground voltage VSS the during the remaining period of the active mode.

If power-down mode is entered during the active mode period or a continuous write operation is performed, the pull-down driving signal SAN may be disabled through control of the pull-down control unit 160. In response thereto, the second pull-down driving unit P1 may drive the pull-down power line SB to the bit line precharge voltage VBLP in response to the disabled pull-down driving signal SAN.

Accordingly, the sense amplification unit 120 may amplify a voltage level of the sub-bit line BLB to the bit line precharge voltage VBLP during power-down mode of the active mode or during the continuous write operation period.

Thereafter, the first precharge unit 140 may precharge the bit line pair BL and BLB to the bit line precharge voltage VBLP during a precharge mode period. The second precharge unit 150 may precharge the pull-up power line RTO and the pull-down power line SB to the bit line precharge voltage VBLP during the precharge mode period.

In other words, according to an embodiment of the present invention, when power-down mode is entered or a continuous write operation is performed, a voltage level of the pull-down power line SB is controlled so that it becomes a level of the bit line precharge voltage VBLP, not a level of the ground voltage VSS. The drain-source voltage Vds of the first to third equalizing transistors MEQ1, MEQ2, and MEQ3 of the first precharge unit 140 and the first and second PMOS transistors MSP1 and MSP2 and first and second NMOS transistors MSN1 and MSN2 of the sense amplification unit 120 can be reduced. Accordingly, an off current can be reduced when the power-down mode is entered or a continuous write operation is performed in the active mode.

FIG. 3 is a circuit diagram of the pull-down control unit 150 shown in FIG. 1.

According to the embodiment of FIG. 3, the pull-down control unit 160 may include a NOR gate NOR1, a NAND gate NAND1, and an inverter INV1.

The NOR gate NOR1 may receive the burst write signal BURST_WT and the power-down mode signal POWER_DN as input and output a pull-down off signal SAN_OFFB. In this case, the burst write signal BURST_WT may be enabled when a continuous write operation is performed in the active mode, and the power-down mode signal POWER_DN may be enabled in the standby mode of the active mode.

The NAND gate NAND1 receives the pull-down control signal SAN_EN and the pull-down off signal SAN_OFFB as input and may control the enabling of the pull-down driving signal SAN. In this case, the pull-down control signal SAN_EN may be a signal for controlling the pull-down driving unit N2 and P1 so that they are driven in the active mode. Accordingly, the pull-down control signal SAN_EN may be a signal enabled in the active mode. The pull-down driving signal SAN may be enabled depending on whether the burst write signal BURST_WT or the power-down mode signal POWER_DN is enabled in the active mode.

In other words, the pull-down driving signal SAN may be enabled when a continuous write operation is performed in the active mode or in the standby mode. In response thereto, the second pull-down driving unit P1 drives the pull-down power line SB to the bit line precharge voltage VBLP. Accordingly, an off current can be reduced because the drain-source voltage of the first precharge unit 140 and the sense amplification unit 120 is reduced.

According to the semiconductor device according to some embodiments of the present invention, there is an advantage in that power consumption can be reduced because an off current is reduced in power-down mode or when a continuous write operation is performed.

Although various embodiments have been described for illustrative purposes, it will be apparent to those skilled in the art that various changes and modifications may be made without departing from the spirit and scope of the invention as defined in the following claims.

1. A semiconductor device, comprising:
a sense amplification unit suitable for sensing and amplifying data loaded onto a data line pair; and
a first pull-down driving unit suitable for supplying a pull-down power line with a first voltage in response to a pull-down driving signal in an active mode;
a second pull-down driving unit suitable for supplying the pull-down power line with a second voltage having a higher voltage level than the first voltage in response to the pull-down driving signal when a power-down mode period is entered in the active mode or when write operations are performed continuously in the active mode, wherein the second voltage corresponds to a half of a core voltage.

2. (canceled)

3. The semiconductor device of claim 1, further comprising a pull-down control unit suitable for controlling whether or not to enable the pull-down driving signal in the active mode.

4-5. (canceled)

6. The semiconductor device of claim 1, further comprising a pull-up driving unit suitable for supplying a pull-up power line with a third voltage having a higher voltage level than the second voltage as a pull-up driving voltage in response to a pull-up driving signal in the active mode.

7. The semiconductor device of claim 6, wherein:
the first voltage includes an externally supplied ground voltage, and
the third voltage includes the core voltage generated by lowering an externally supplied power supply voltage.

8. The semiconductor device of claim 7, further comprising:
a first precharge unit suitable for precharging the data line pair to the precharge voltage in a precharge mode after the active mode; and
a second precharge unit suitable for precharging the pull-up power line and the pull-down power line to the precharge voltage in the precharge mode.

9. A semiconductor device, comprising:
a bit line pair including a main bit line and a sub-bit line;
a memory cell coupled to any one of the main bit line and the sub-bit line;
a sense amplification unit suitable for sensing and amplifying data loaded onto the bit line pair;
a pull-up driving unit suitable for supplying a pull-up power line with a first voltage in response to a pull-up driving signal in an active mode; and
a pull-down driving unit suitable for supplying a pull-down power line with a second voltage in response to a pull-down driving signal in the active mode,
wherein the pull-down driving unit supplies the pull-down power line with a third voltage having a lower voltage level than the first voltage and having a higher voltage level than the second voltage, in response to the pull-down driving signal when a power-down mode period is entered in the active mode or when write operations are performed continuously in the active mode, the third voltage corresponding to a half of a core voltage.

10. The semiconductor device of claim 9, wherein the pull-down driving unit comprises:
a first pull-down driving unit suitable for supplying the pull-down power line with the second voltage in response to the pull-down driving signal in the active mode; and
a second pull-down driving unit suitable for supplying the pull-down power line with the third voltage in response to the pull-down driving signal in the active mode.

11. The semiconductor device of claim 9, further comprising a pull-down control unit suitable for controlling whether or not to enable the pull-down driving signal in the active mode.

12-13. (canceled)

14. The semiconductor device of claim 9, wherein:
the first voltage includes the core voltage generated by lowering an external power supply voltage, and
the second voltage includes an externally supplied ground voltage.

15. The semiconductor device of claim 14, further comprising:
a first precharge unit suitable for precharging the data line pair to the precharge voltage in a precharge mode after the active mode; and
a second precharge unit suitable for precharging the pull-up power line and the pull-down power line to the precharge voltage in the precharge mode.
